(19) United States
(12) Patent Application Publication
(10) Pub. No.: US 2026/0194585 A1
(43) Pub. Date: Jul. 9, 2026

(54) OCV EVALUATION METHOD BASED ON VOLTAGE CURVE

(71) Applicant: TEXAS INSTRUMENTS INCORPORATED, Dallas, TX (US)

(72) Inventors: Yicheng ZHOU, Wuxi Jiangsu (CN); Kangcheng XU, Shanghai (CN); Zixuan BAI, Shanghai (CN); Chao GAO, Shanghai (CN)

(21) Appl. No.: 19/014,021

(22) Filed: Jan. 8, 2025

(51) Int. Cl. G01R 31/3842; G01R 31/389

(52) U.S. Cl. CPC G01R 31/3842; G01R 31/389

(57) ABSTRACT

In some examples, a device is configured to determine, at a first time, a first cell voltage of a battery cell. The device is also configured to determine, at a second time, a second cell voltage of the battery cell. The device is also configured to estimate a future cell voltage of the battery cell using the first cell voltage and the second cell voltage, the future cell voltage for a third time subsequent to the second time. The device is also configured to estimate an open circuit voltage of the battery cell using the estimated future cell voltage of the battery cell, an impedance of the battery cell, and a current measurement of the battery cell at the second time.

### BACKGROUND

A battery may be characterized by various criteria, such as an open circuit voltage (OCV), a state of charge (SOC), or the like. Values or measurements for determining these criteria may be determined according to varied approaches, each of which includes various shortcomings.

### SUMMARY

In some examples, a device is configured to determine, at a first time, a first cell voltage of a battery cell. The device is also configured to determine, at a second time, a second cell voltage of the battery cell. The device is also configured to estimate a future cell voltage of the battery cell using the first cell voltage and the second cell voltage, the future cell voltage for a third time subsequent to the second time. The device is also configured to estimate an open circuit voltage of the battery cell using the estimated future cell voltage of the battery cell, an impedance of the battery cell, and a current measurement of the battery cell at the second time.

In some examples, a method includes determining, at a first time via a controller, a first cell voltage of a battery cell. The method also includes determining, at a second time via the controller, a second cell voltage of the battery cell. The method also includes estimating, via the controller, a future cell voltage of the battery cell using the first cell voltage and the second cell voltage, the future cell voltage for a third time subsequent to the second time.

In some examples, a system includes a battery, a processor, and a management circuit coupled to the battery and the processor. The management circuit is configured to determine, at a first time, a first cell voltage of a battery cell. The management circuit is also configured to determine, at a second time, a second cell voltage of the battery cell. The management circuit is also configured to estimate a future cell voltage of the battery cell using the first cell voltage and the second cell voltage, the future cell voltage for a third time subsequent to the second time. The management circuit is also configured to estimate an open circuit voltage of the battery cell using the estimated future cell voltage of the battery cell, an impedance of the battery cell, and a current measurement of the battery cell at the second time. The management circuit is also configured to provide the estimated open circuit voltage of the battery to the processor.

### BRIEF DESCRIPTION OF THE DRAWINGS

FIG. 1 is a block diagram of an illustrative example of a wireless battery management system (WBMS).

FIG. 2 is a block diagram of an example implementation of the WBMS of FIG. 1.

FIG. 3A is a diagram of example battery cell voltage with respect to time.

FIG. 3B is a diagram of example battery cell voltage factor with respect to time.

FIG. 3C is a diagram of example measured and estimated Vcell values with respect to time.

FIG. 3D is a diagram of example deltaV values for FIG. 3C.

FIG. 4A is a diagram of example battery cell voltage with respect to time.

FIG. 4B is a diagram of example battery cell voltage factor with respect to time.

FIG. 4C is a diagram of example measured and estimated Vcell values with respect to time.

FIG. 4D is a diagram of example deltaV values for FIG. 4C.

FIG. 5 is a flowchart of an example method of OCV estimation.

FIG. 6 is a diagram showing an example of OCV with respect to SOC.

FIG. 7 is a flowchart of an example method of SOC estimation.

FIG. 8 is a flowchart of an example method of SOC estimation.

### DETAILED DESCRIPTION

As described above, a battery, which may include multiple battery cells, may be characterized by various criteria, such as an open circuit voltage (OCV), a state of charge (SOC), or the like. These criteria may be useful for various applications, such as determining whether operation of a battery or battery cell is anomalous, determining whether a battery or battery cell has a sufficient charge for a particular purpose, recommending to recharge the battery or battery cell, reporting the criteria to a user of a system including or powered at least in part by the battery or battery cell, or the like. The SOC may be determined based at least in part on the OCV. Some approaches to determining the OCV include using a rest voltage of the battery as the OCV, predicting a value of the OCV through a least-square approach, by best fitting a relaxation model, or by use of a controlled auto-regressive and moving average (CARMA) model. However, each of these approaches can suffer from various shortcomings in some examples, such as a large error rates, an extended amount of time for determination, or large computing resource requirements for calculation. Similarly, by directly determining the SOC using the OCV, accuracy may be adversely affected, such as resulting from detection error in determining the OCV.

Examples of this disclosure provide for determination of OCV of a battery cell. In some examples, the OCV is determined by determining a cell voltage of a battery cell at first and second times and from those determined cell voltages, estimating a future cell voltage of the battery cell. The estimated future cell voltage of the battery cell is then added to a sum of a cell current of the battery cell (Icell) and a resistance of the battery cell (Rcell) (where the sum may be abbreviated by IRcell) to provide the OCV of the battery cell. Using the determined OCV, the SOC of the battery cell may then be estimated. For example, SOC may be estimated according to a data fusion process that combines voltage and current information of the battery cell. For example, a first SOC term may be determined using the determined OCV and an estimated error associated with the determined OCV. A second SOC term may be determined using the estimated SOC from a preceding point in time and a relationship between a rate of change in charge of the battery cell to an estimated maximum charge capacity of the battery cell. Using the first and second SOC terms, and in some examples an error term, a current estimated SOC for the battery cell may be determined. The techniques described herein may provide better accuracy, higher reliability, and/or lower computational intensity, as compared to other approaches.

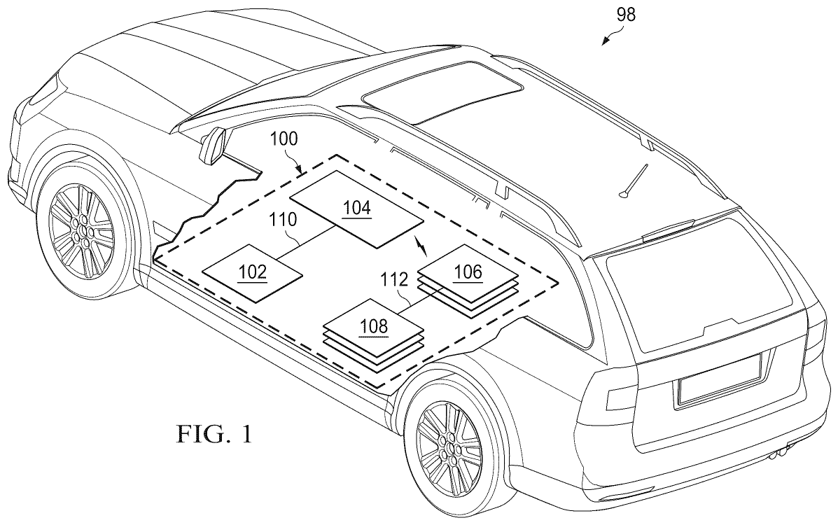

FIG. 1 is a block diagram of an illustrative example of a wireless battery management system (WBMS). FIG. 1 includes an example environment 98 and an example WBMS 100. The example WBMS 100 includes a primary network node 104, a battery controller 102, a plurality of secondary network nodes 106, a plurality of battery cells 108, and wired connections 110 and 112.

The environment 98 refers to any use case that may include a WBMS to supply power to one or more components. In FIG. 1, the environment 98 is an automotive system such as an electric vehicle (EV) or a hybrid EV (HEV), an electronic device (e.g., a mobile device such as a smartphone or laptop), a power tool, or an embedded system. In other examples, the environment 98 is unrelated to the automotive industry, such as a computing device, personal electronic device, or the like.

The battery controller 102 determines different communication schedules within superframe or other communication intervals, thereby supporting heterogeneous battery modules in accordance with the teachings of this disclosure. The different communication schedules are used by the secondary network nodes 106 to send messages to the battery controller 102. In some examples, these messages may include criteria related to at least some of the battery cells 108 coupled to a respective one of the secondary network nodes 106 that performs the sending. In some examples, these messages may include a SOC for at least some of the battery cells 108 coupled to a respective one of the secondary network nodes 106 that performs the sending. In some examples, the battery controller 102 performs actions based on the messages. The battery controller 102 is discussed further in connection with examples described below.

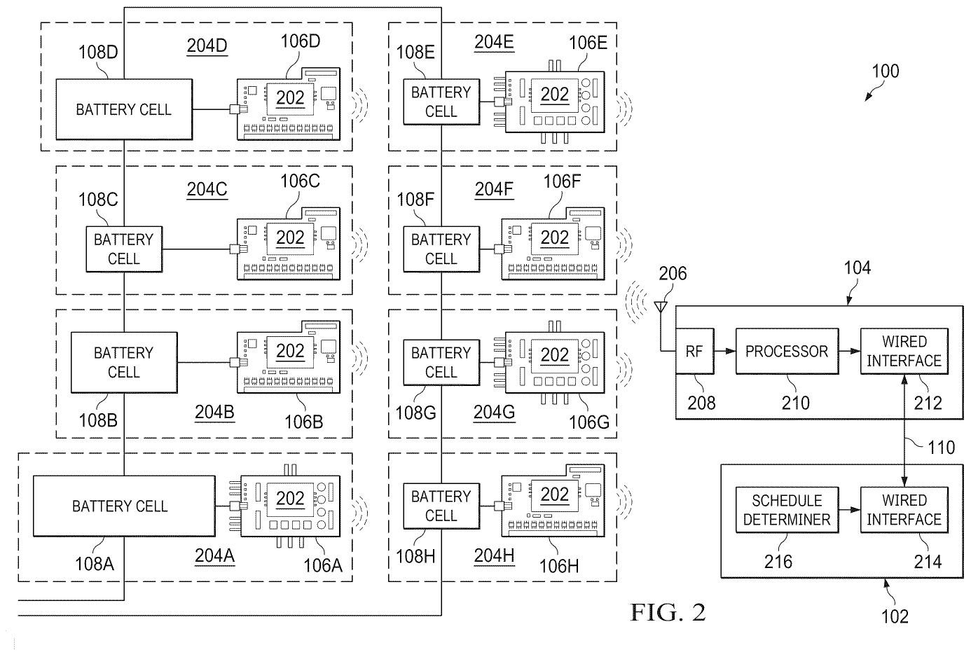

The primary network node 104 establishes communication between the battery controller 102 and the secondary network nodes 106. The primary network node 104 is coupled to the battery controller 102 using wired connection 110. Example communication protocols used over the first wired connection 110 between the primary network node 104 and the battery controller 102 is a universal asynchronous receiver/transmitter (UART), inter-integrated circuit (I2C), controller area network (CAN) bus, etc. In FIG. 1, the WBMS 100 includes a single primary network node 104. In other examples, a WBMS may include a plurality of primary network nodes. The primary network node 104 is discussed further in connection with FIG. 2.

The secondary network nodes 106 communicate with the battery controller 102 regarding the respective battery cells 108. The communications may describe any type of data, including but not limited to performance metrics, SOC, status updates, renegotiations, emergency codes, etc., of the battery cells 108. The secondary network nodes 106 also provide requests for transmissions within a superframe interval in accordance with the teachings of this disclosure. The secondary network nodes 106 are wirelessly coupled to the primary network node 104 and coupled to the battery cells 108 using the wired connection 112. The secondary network nodes 106 may implement any number of suitable hardware components, including but not limited to terminals, antennae, transmitters, receivers, etc., to support both wired and wireless communications. Although this disclosure describes the WBMS 100 primarily in the context of wireless systems, these techniques may also be useful for wired systems (e.g., where the connection between primary network node 104 and secondary network nodes 106 is wired). The secondary network nodes 106 are discussed further in connection with FIG. 2.

FIG. 2 is a block diagram of an example implementation of the WBMS 100 of FIG. 1. The WBMS 100 of FIG. 2 may be instantiated (e.g., creating an instance of, bring into being for any length of time, materialize, implement, etc.) by programmable circuitry such as a central processor unit (CPU) executing first instructions. Additionally, or alternatively, the WBMS 100 of FIG. 2 may be instantiated (e.g., created an instance of, brought into being for any length of time, materialized, implemented, etc.) by: (i) an application specific integrated circuit (ASIC); and/or (ii) a field programmable gate array (FPGA) structured and/or configured in response to execution of second instructions to perform operations corresponding to the first instructions. Some or all of the circuitry of FIG. 2 may be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

The example block diagram of FIG. 2 includes the battery controller 102, primary network node 104, secondary network nodes 106A-106H (which collectively form secondary network nodes 106), and battery cells 108A-108H (which collectively form battery cells 108). Each of the secondary network nodes 106 include example schedule requester circuitry 202. As used herein, a secondary network node 106A and its corresponding battery cell 108A are collectively referred to as a battery module 204A. Accordingly, the battery modules 204A-204H collectively form the battery modules 204. The primary network node 104 includes an example antenna 206, example radio frequency (RF) circuitry 208, an example processor 210 and example wired interface circuitry 212. The battery controller 102 includes example wired interface circuitry 214 and example schedule determiner circuitry 216. While FIG. 2 shows eight battery modules 204 and one battery controller 102, in other examples, the WBMS 100 includes any number of battery modules 204 and battery controllers 102. For example, WBMS 100 may include two or more battery controllers 102, where a first set of the secondary network nodes 106 are assigned to communicate with a first battery controller 102, and a second set of the secondary network nodes 106 are assigned to communicate with a second battery controller 102. The first and second sets of secondary network nodes 106 may or may not overlap.

The battery modules 204 wirelessly communicate with the primary network node 104 using consecutive superframe intervals. For example, a first superframe containing a first set of communications is followed by a second superframe containing a second set of communications, etc. Within a given battery module 204A, the schedule requester circuitry 202 determines whether a transmission regarding the corresponding battery cell 108A should be made in an upcoming superframe interval. The schedule requester circuitry 202 may determine whether to make a transmission based on factors that include but are not limited to status and performance of the corresponding battery cell 108A.

The schedule requester circuitry 202 optionally requests to be included on a schedule for an upcoming superframe interval based on the result of the determination and in accordance with the teachings of this disclosure. Accordingly, the battery modules 204 do not request to make a transmission in an upcoming superframe interval every time an opportunity to make a request is available. The schedule requester circuitry 202 may provide additional information to the battery controller 102 when requesting a transmission in an upcoming superframe interval. For example, the schedule requester circuitry 202 may request an extra uplink allocation in addition to the transmission slot that is normally allocated in a default schedule. The schedule requester circuitry 202 may also request a specific number of requested time slots, request a specific duration of uplink time, and/or request a specific data size to uplink (e.g., a specific number of blocks, bytes, or bits), etc. Alternatively, the request sent by the schedule requester circuitry 202 may indicate only that a corresponding battery module 204A is requesting more time for transmission, without any specifics about the requested time duration, number of time slots, or uplink size.

In the example of FIG. 2, each instance of the schedule requester circuitry 202 is implemented within the secondary network nodes 106. In other examples, one or more instances of the schedule requester circuitry 202 are implemented elsewhere within the respective battery modules 204. In some examples, the schedule requester circuitry 202 is instantiated by programmable circuitry executing schedule requester instructions.

Within the primary network node 104, the RF circuitry 208 communicates wirelessly with the secondary network nodes 106 via the antenna 206. The RF circuitry 208 may use the license-free 2.4 gigahertz (GHz) industrial, scientific, and medical (ISM) band from 2.4 GHz to 2.483 GHZ, which is compliant with the Bluetooth Special Interest Group (SIG). Additionally, or alternatively, the RF circuitry 208 may use 2 megabits per second (Mbps) Bluetooth Low Energy (BLE) across the physical layer (PHY). The Open Systems Interconnection (OSI) model includes the physical layer (PHY) as a layer used for communicating raw bits over a physical medium. In examples described herein, the PHY is free space, which the WBMS 100 uses to wirelessly communicate between the primary network node 104 and the secondary network nodes 106. In some examples, the RF circuitry 208 is instantiated by programmable circuitry executing RF instructions.

Within the primary network node 104, the processor 210 both interprets the contents of data received by the primary network node 104 and determines the contents of data to be transmitted by the primary network node 104. In doing so, the processor 210 helps establish communication between the battery modules 204 and the battery controller 102. The processor 210 may be implemented by any type of programmable circuitry. Examples of programmable circuitry include but are not limited to programmable microprocessors, FPGAs that may instantiate instructions, CPUs, graphics processor units (GPUs), digital signal processors (DSPs), X processing units (XPUs), or microcontrollers and integrated circuits such as ASICs.

Within the primary network node 104, the wired interface circuitry 212 sends and receives communications with the battery controller 102 via the wired connection 110. The wired interface circuitry 212 may implement any suitable hardware components, including but not limited to terminals, pins, interconnects, etc., to implement wired communications.

Similarly, within the battery controller 102, the wired interface circuitry 214 sends and receives communications with the primary network node 104 via the wired connection 110. The wired interface circuitry 214 may implement any suitable hardware components to implement wired communications.

The schedule determiner circuitry 216 determines different communication schedules for different superframe intervals, thereby supporting heterogeneous battery modules in accordance with the teachings of this disclosure. The schedule determiner circuitry 216 adjusts a schedule and/or creates new schedules for superframe intervals based on the transmission request transmitted by the multiple instances of the schedule requester circuitry 202.

In the example of FIG. 2, the schedule determiner circuitry 216 is implemented within the battery controller 102. In other examples, the schedule determiner circuitry 216 is implemented within the primary network node 104 or elsewhere within the WBMS 100. In some examples, the schedule determiner circuitry 216 is instantiated by programmable circuitry executing schedule determiner instructions.

The battery modules 204 are heterogeneous in the sense that the design, manufacture, capabilities, and/or performance of a first battery module 204 may differ from that of a second battery module 204. For example, in FIG. 2, battery cells 108A, 108B, 108D store a larger amount of charge than battery cells 108C, 108E-108H. Furthermore, the amount of charge stored in battery cells 108A, 108B, 108D is nonuniform. In an additional example, FIG. 2 illustrates the secondary network nodes 106A, 106E, 106G implemented by a first type of programmable circuitry, and secondary network nodes 106B-106D, 106F, 106H implemented by a different type of programmable circuitry. While the example FIG. 2 illustrates variance in battery capacity and type of programmable circuitry, in practice, the battery modules 204 may include other types of differences.

In some examples, the heterogeneity of the WBMS 100 causes some battery modules 204 to seek communication with the battery controller 102 more frequently than other battery modules 204. Some battery modules 204 may additionally or alternatively transmit different types of information within a superframe interval than other battery modules 204. For example, the battery module 204A may seek to report a storage capacity measurement (such as the SOC) when the battery module 204B seeks to report an error code. The battery controller 102 enables such diverse forms of communication by obtaining requests for transmissions sent by the battery modules 204 and determining a schedule for each superframe interval. The battery controller 102 may use different schedules for different superframe intervals. Therefore, if a first superframe interval is not long enough to support all the transmissions concurrently requested by the battery modules 204, the battery controller 102 can create a first schedule where a first subset of battery modules 204 transmit information and a second schedule where a second subset of battery modules 204 transmit information. Accordingly, the WBMS 100 coordinates the battery modules 204 to communicate within superframe intervals of a fixed period of time, even when the information communicated varies by length and priority between battery modules 204.

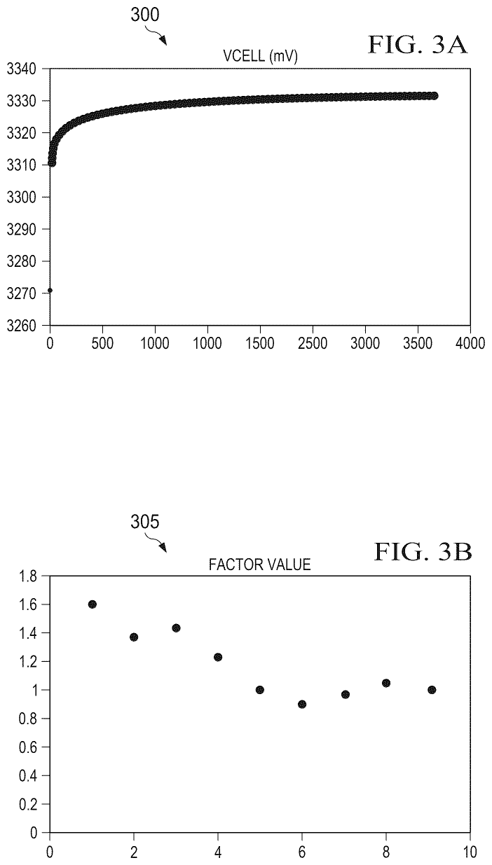

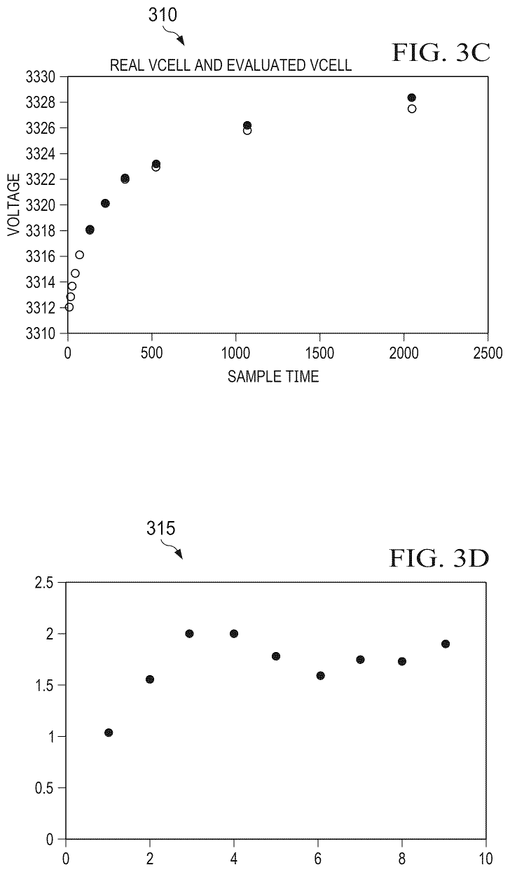

FIG. 3A is a diagram 300 of example battery cell voltage with respect to time. In FIG. 3A, a vertical axis is representative of voltage in units of millivolts (mV) and a horizontal axis is representative of time in units of seconds(s). The diagram 300 of FIG. 3A is representative of a cell voltage (Vcell) behavior of a battery cell following a discharge event of the battery cell. As time elapses following an end of the discharge event, the cell voltage of the battery cell recovers, such as to approximately 3300 mV, for the example shown in FIG. 3A.

FIG. 3B is a diagram 305 of example battery cell voltage factor with respect to time. In FIG. 3B, a vertical axis is representative of the voltage factor is real number units and a horizontal axis is representative of a sample time for a battery cell voltage. The diagram 305 of FIG. 3B is representative of a relationship between adjacent values of Vcell. For example, a relationship between a subsequent value of Vcell and a current value of Vcell may have approximately a fixed value relationship to the current value of Vcell and a preceding value of Vcell. This fixed value relationship is the voltage factor. In some examples, this fixed value relationship may be approximately equal to 1. The voltage factor may be approximately equal to the following equation 1, where F is the voltage factor and n is an index (e.g., sample index) value representative of a time at which a sample is taken (e.g., Vcell is measured).

$$F = \frac{{Vcell}_{n + 1} - {Vcell}_{n}}{{Vcell}_{n} - {Vcell}_{n - 1}} \qquad ( 1 )$$

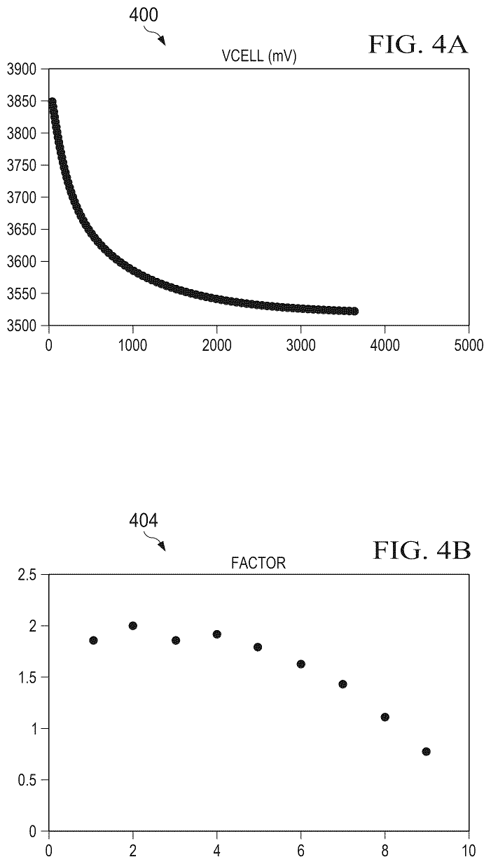

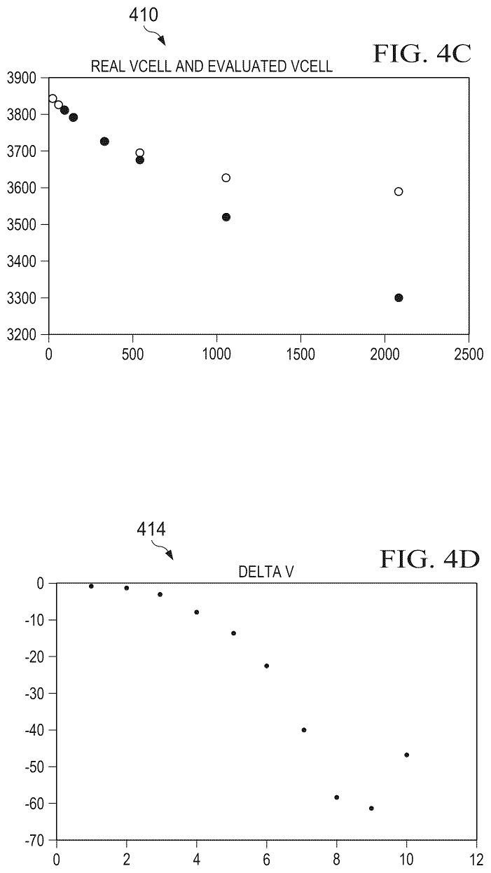

Thus, as shown in FIG. 4B, for n=5, (Vcell₆-Vcell₅)/(Vcell₅-Vcell₄) is approximately equal to 1. Similar determinations may be made for other values of n. Because of this fixed value relationship, future values of Vcell may be estimated based on a current value of Vcell and a preceding value of Vcell. For example, a value for Vcell at any index value x, where x is selected from among the index values representative of time at which a sample is taken and x is greater than n, may be determined according to the following equation 2.

$${Vcell}_{x} = ( x - n ) * ( {Vcell}_{n} - {Vcell}_{n - 1} ) + {Vcell}_{n} \qquad ( 2 )$$

A mapping of index values representative of time at which a sample is taken to times in units of seconds is shown in Table 1. In an example, for each increase in value of n, the time is multiplied by 2. In other examples, for each increase in value of n, the time is multiplied by any suitable positive number.

TABLE 1

| Index | Time |
|---|---|
| 1 | 2 |
| 2 | 4 |
| 3 | 8 |
| 4 | 16 |
| 5 | 32 |
| 6 | 64 |
| 7 | 128 |
| 8 | 256 |
| 9 | 512 |
| 10 | 1024 |
| 11 | 2048 |
| 12 | 4096 |
| 13 | 8192 |
| 14 | 16384 |
| 15 | 32768 |

As described above with respect to FIG. 3A, as time increases Vcell settles to a steady-state value. Thus, accuracy of a measurement of Vcell with respect to that steady-state value of Vcell increases as time increases. For example, for n=11 the error may be approximately equal to 1 mV, for n=10 the error may be approximately equal to 2 mV, for n=9 the error may be approximately equal to 4 mV, and the like. Therefore, it may be useful in obtaining an accurate Vcell measurement with respect to the steady-state value of Vcell to delay determination of Vcell, such as to a value of Vcell at index 11 or greater. In other use cases, an index value for a time at which it is useful for determining Vcell may be determined based on an amount of error tolerable for that use case. However, it may be impractical in many application environments to wait 2048 seconds or greater to determine the value of Vcell following completion of a discharge event. Therefore, Vcell may be estimated according to the above equation 2 for a time of interest of Table 1 by determining the value of Vcell for any two adjacent index values corresponding to times of Table 1 that precede the time of interest.

FIG. 4C is a diagram 310 of example measured and estimated Vcell values with respect to time. In FIG. 4C, a vertical axis is representative of voltage in units of mV and a horizontal axis is representative of time in units of s. The diagram 310 includes estimated values of Vcell for a value of n=5. As shown by the diagram 310, the estimated values of Vcell approximately equal the measured values of Vcell, with an error between the estimated value of Vcell and the measured value of Vcell that increases as n increases.

From the estimated value of Vcell determined according to the above equation 2, the OCV of the battery cell may be estimated according to the following equation 3 in which Iₙ is a measurement of current flow through the battery cell at the time corresponding to index n and Rcell is an impedance value of the battery cell as specified in manufacturing data of the battery cell. For example, Rcell may be determinable from a data sheet including data for the battery cell, a manufacturer's specification listing of the battery cell indicating electrical characteristics of the battery cell, or the like.

$$OCV = {Vcell}_{x} + {I}_{n} * {R}_{cell} \qquad ( 3 )$$

FIG. 3D is a diagram 315 of example differences between adjacent values of Vcell. In FIG. 3D, a vertical axis is representative a voltage difference in units of mV and a horizontal axis is representative of a sample time for a battery cell voltage, such as the index values of Table 1. For example, FIG. 3D may be representative of values for Vcellₙ₊₁−Vcellₙ, such as used in equation 1, provided above. In some examples, the voltage factor described above with respect to FIG. 3B may be unusable, such as in operational conditions in which a battery has been at rest for an extended period of time. In such operation conditions, Vcellₙ−Vcellₙ₋₁ may have a value of approximately 0, causing the above equation 1 to become undefined. In such examples, a value as shown in FIG. 3D may be used in place of a value determined according to equation 1 for a value of n that results in equation 1 being undefined.

FIG. 4A is a diagram 400 of example battery cell voltage with respect to time. In FIG. 4A, a vertical axis is representative of voltage in units of mV and a horizontal axis is representative of time in units of s. The diagram 400 of FIG. 4A is representative of Vcell of a battery cell following a charge event of the battery cell. As time elapses following an end of the charge event, the cell voltage of the battery cell recovers, such as to approximately 3500 mV, for the example shown in FIG. 4A.

FIG. 4B is a diagram 405 of example battery cell voltage factor with respect to time. In FIG. 4B, a vertical axis is representative of the voltage factor is real number units and a horizontal axis is representative of a sample time for a battery cell voltage, such as the index values of Table 1. The diagram 405 of FIG. 4B is representative of a relationship between adjacent values of Vcell. For example, a relationship between a subsequent value of Vcell and a current value of Vcell may have approximately a fixed value relationship to the current value of Vcell and a preceding value of Vcell. This fixed value relationship is the voltage factor. The voltage factor may be approximately equal to the equation 1, as described above.

Thus, as shown in FIG. 4B, for n=5, (Vcell₆−Vcell₅)/(Vcell₅−Vcell₄) is approximately equal to 1.75. Similar determinations may be made for other values of n. Because of this fixed value relationship, future values of Vcell may be estimated based on a current value of Vcell and a preceding value of Vcell according to equation 2, as described above.

As described above, as time increases Vcell settles to a steady-state value. Thus, accuracy of a measurement of Vcell with respect to that steady-state value of Vcell increases as time increases. For example, for n=11 the error may be approximately equal to 1 mV, for n=10 the error may be approximately equal to 2 mV, for n=9 the error may be approximately equal to 4 mV, and the like. Therefore, it may be useful in obtaining an accurate Vcell measurement with respect to the steady-state value of Vcell to delay determination of Vcell, such as to a value of Vcell at index 11 or greater. In other use cases, an index value for a time at which it is useful for determining Vcell may be determined based on an amount of error tolerable for that use case. However, it may be impractical in many application environments to wait 2048 seconds or greater to determine the value of Vcell following completion of a charge event. Therefore, Vcell may be estimated according to the above equation 2 for a time of interest of Table 1 by determining the value of Vcell for any two adjacent index values corresponding to times of Table 1 that precede the time of interest.

FIG. 4C is a diagram 410 of example measured and estimated Vcell values with respect to time. In FIG. 4C, a vertical axis is representative of voltage in units of mV and a horizontal axis is representative of time in units of s. The diagram 410 includes estimated values of Vcell for a value of n=5. As shown by the diagram 410, the estimated values of Vcell approximately equal the measured values of Vcell, with an error between the estimated value of Vcell and the measured value of Vcell that increases as n increases. OCV of the battery cell following completion of the charge event may correspondingly be estimated according to the above equation 3.

FIG. 4D is a diagram 415 of example differences between adjacent values of Vcell. In FIG. 4D, a vertical axis is representative a voltage difference in units of mV and a horizontal axis is representative of a sample time for a battery cell voltage, such as the index values of Table 1. For example, FIG. 4D may be representative of values for Vcellₙ₊₁−Vcellₙ, such as used in equation 1, provided above. In some examples, the voltage factor described above with respect to FIG. 4B may be unusable, such as in operational conditions in which a battery has been at rest for an extended period of time. In such operation conditions, Vcellₙ−Vcellₙ₋₁ may have a value of approximately 0, causing the above equation 1 to become undefined. In such examples, a value as shown in FIG. 4D may be used in place of a value determined according to equation 1 for a value of n that results in equation 1 being undefined.

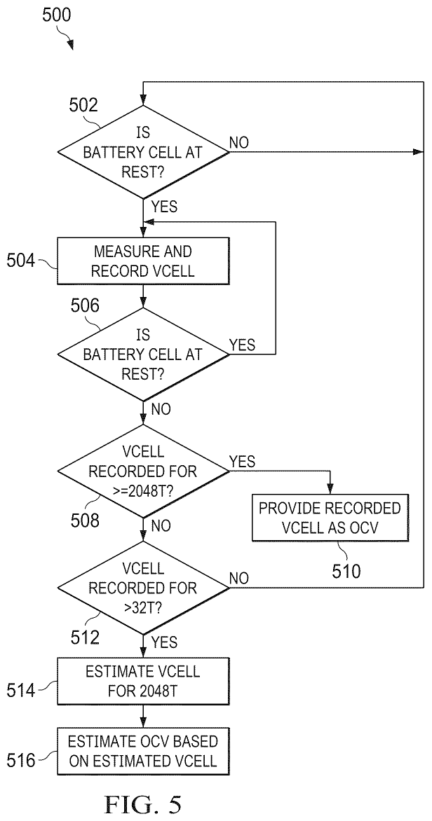

FIG. 5 is a flowchart of an example method 500 of OCV estimation. In an example, the method 500 is implemented at least in part by a controller, processor, microprocessor, or other device having computational and/or instruction execution capacity. In some examples, the method 500 is implemented at least in part by a secondary network node 106 for determining OCV of one or more battery cells 108 to which the secondary network node 106 is coupled. In this way, the secondary network node 106 may be, or include, a management circuit or device that manages one or more battery cells 108 to which the secondary network node 106 is coupled. The method 500 is implemented, in some examples, to determine an estimated future value of Vcell based on based on multiple measured values of Vcell, and from that estimated future value of Vcell, determine OCV of the battery cell.

At operation 502, a determination is made regarding whether a coupled battery cell is at rest. In an example, the battery cell is determined to be at rest responsive to a current flow through the battery cell having a value less than a programmed threshold for a programmed duration of time. In some examples, the programmed threshold may be less than or equal to about 10 mA and the programmed duration of time may be about 16 s. Responsive to the current flow through the battery cell having the value less than the programmed threshold for the programmed duration of time, the battery is determined to be at rest and the method 500 proceeds to operation 504. Responsive to the current flow through the battery cell not having the value less than the programmed threshold for the programmed duration of time, the battery cell is determined to not be at rest and the method 500 remains at operation 502.

At operation 504, Vcell for the battery cell is measured and recorded. In some examples, Vcell is measured and recorded at square of two times. For example, Vcell may be measured and recorded for 2T, 4T, . . . 2048T, where T equals 1 second. Operation 504 may be iteratively performed while the battery cell remains at rest. Thus, for a first execution of operation 504, Vcell is measured and recorded for 2T. For a second execution of operation 504, Vcell is measured and recorded for 4T. For a third execution of operation 504, Vcell is measured and recorded for 4T, and so on. Following recording of Vcell corresponding to a particular time, the method 700 proceeds to operation 506.

At operation 506, a determination is made regarding whether the battery cell remains at rest. The determination may be made according to the same criteria and in the same manner as described above with respect to operation 502. Responsive to the battery cell remaining at rest, the method 500 returns to operation 504 to record Vcell at a next square of two time. Responsive to the battery cell not remaining at rest, the method 500 proceeds to operation 508.

At operation 508, a determination is made regarding whether Vcell has been recorded for >=2048T (e.g., n=11 according to the mapping of Table 1). Responsive to Vcell having been recorded for >=2048T, the method 500 continues to operation 510. Responsive to Vcell not having been recorded for >=2048T, the method 500 continues to operation 512.

At operation 510, the recorded Vcell is provided as the OCV to another device, such as transmitted from the secondary network node 106 to the primary network node 104, displayed or reported to a user, stored, or the like, the scope of which is not limited herein.

At operation 512, a determination is made regarding whether Vcell has been recorded for >=32T (e.g., n=5 according to the mapping of Table 1) and <2048T (e.g., n=11 according to the mapping of Table 1). In other examples, the determination may be made regarding whether Vcell has been recorded for any suitable value of n (e.g., any suitable time) based on an amount of error tolerable for a particular use case. Responsive to Vcell having been recorded for a time in the above range, the method 500 continues to operation 514. Responsive to Vcell not having been recorded for a time in the above range, the method 500 returns to operation 502.

At operation 514, a future value of Vcell is estimated. In some examples, the future value of Vcell is estimated for n=11 (e.g., 2048T or a time of 2048 seconds). In other examples, the future value of Vcell is estimated for any index value n, corresponding to any suitable future time. In an example, the future value of Vcell is estimated according to equation 2, as described above, based on the most recently recorded adjacent set of values of Vcell.

At operation 516, OCV is estimated based on the estimated future value of Vcell. In an example, OCV is estimated based on equation 3, as described above. The estimated OCV may be provided to another device, such as transmitted from the secondary network node 106 to the primary network node 104, displayed or reported to a user, stored, or the like, the scope of which is not limited herein.

In some examples, the method 500 may repeat, such as progressing from operation 510 or 516, as appropriate, to operation 502 to record or estimate an OCV value for a subsequent time.

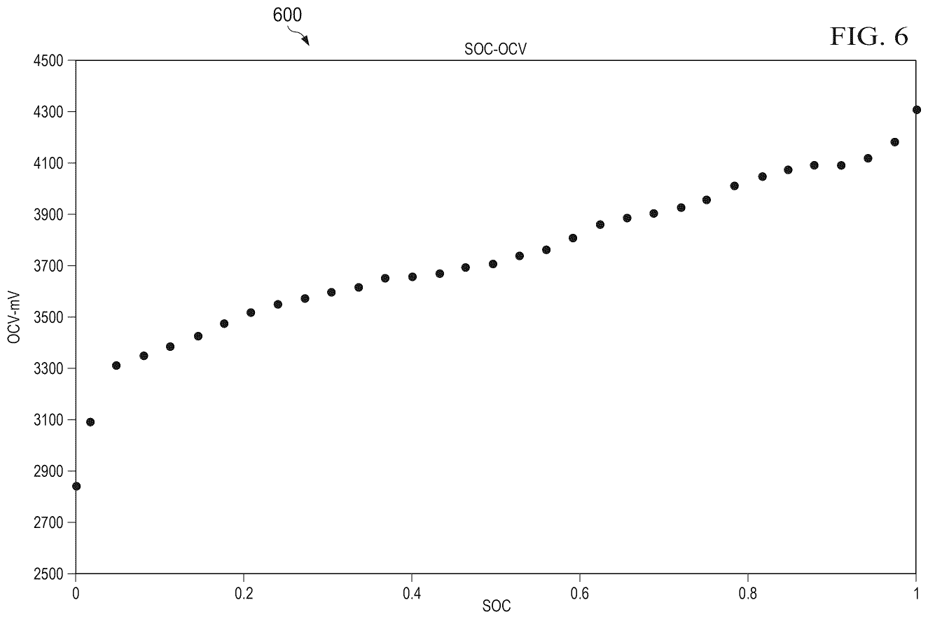

FIG. 6 is a diagram 600 showing an example of OCV with respect to SOC. In FIG. 6, a vertical axis is representative of OCV in units of mV and a horizontal axis is representative of SOC in terms of percentage (e.g., percentage of a maximum capacity of a battery cell). As shown by the diagram 600, by determining the estimated value of OCV for a battery cell, such as according to method 500 of FIG. 5 and/or equation 3, as described above, an estimated SOC value may be determined. For example, the estimated value of SOC at a time n (e.g., as selected from among times corresponding to index values n of Table 1), indicated as [symbol] ₙ, may be determined according to the following equation 4.

$${\text{?}}_{n} = SOC {1}_{n} + k {s}_{n} ( SOC {2}_{n} - SOC {1}_{n} ) \qquad ( 4 )$$

In the above equation 4, SOC1ₙ is determined based on the OCV according to the following equation 5, SOC2ₙ is determined according to the following equation 6, and ksₙ is determined according to the following equation 7.

$$SOC {1}_{n} = {a}_{n} * {OCV}_{n} + {b}_{n} \qquad ( 5 )$$

$$SOC {2}_{n} = {\text{?}}_{n - 1} + \frac{Δ {Q}_{n}}{{\hat{Q}}_{m {ax}_{n - 1}}} + w \qquad ( 6 )$$

$${k s}_{n} = \frac{{δ}_{SOC {1}_{n}}^{2}}{{δ}_{SOC {1}_{n}}^{2} + {δ}_{SOC {2}_{n}}^{2}} \qquad ( 7 )$$

$${δ}_{SOC {1}_{n}}^{2} = {( {a}_{{n}_{m ax}} {δ}_{{OCV}_{n}} )}^{2} \qquad ( 8 )$$

$${δ}_{SOC {2}_{n}}^{2} = {δ}_{{SOC}_{n - 1}}^{2} + {( Δ {Q}_{n} )}^{2} {( {δ}_{\frac{1}{{\hat{Q}}_{m {ax}_{n - 1}}}} )}^{2} + {δ}_{w}^{2} \qquad ( 9 )$$

In the above equation 5, aₙ and bₙ are the slope and intercept, respectively, of a line segment of a theoretical SOC-OCV curve of the battery after segment linearization of the theoretical SOC-OCV curve. In the above equation 6, [symbol] ₙ₋₁ is an immediately preceding estimated value of SOC, ΔQₙ is determined according to the following equation 10, \hat{Q}ₘₐₓ_{_{n−1}} is an estimated value for Qₘₐₓ_{_{n−1}} and is determined according to the following equation 12. In equation 9,

$${δ}_{w}^{2}$$

is an error term which, in some examples, is representative of process noise, primarily representing ΔQₙ offset error, and is approximately equal to 0 with a variance of ±0.000025. In the above equations 7 and 8,

$${δ}_{SOC {1}_{n}}^{2}$$

is a variance associated with a normal distribution of SOC1ₙ, where δ_{ocv}_{ₙ}_{≅±}2 mV at n≥10 and δ_{ocv}_{ₙ} increases in power of two increments for each integer decrease in value of n for n>0. Also in equation 8, aₙ_{ₘₐₓ} is a slope of a line segment of a theoretical SOC-OCV curve of the battery after segment linearization of the theoretical SOC-OCV curve having the greatest value selected from among all line segments existing in a range between the value of the mean of a normal distribution range of the OCV value minus a variance of the normal distribution (e.g., QCVₙ-δ_{ocv}_{ₙ}) and the mean of the normal distribution range of the OCV value plus the variance of the normal distribution (e.g., OCVₙ+δ_{ocv}_{ₙ}). In an example, the theoretical SOC-OCV curve is formed based on a battery performance/behavior model or other characteristics of the battery provided by a manufacturer of the battery. In the above equations 7 and 9.

$${δ}_{SOC {2}_{n}}^{2}$$

iS a variance associated with a normal distribution of SOC2ₙ.

$$Δ {Q}_{n} = \sum ( I ( t ) + {I}_{Offset} ) * Δ t \qquad ( 10 )$$

$${Q}_{m {ax}_{n}} = \frac{Δ {Q}_{n}}{{\text{?}}_{n} - {\text{?}}_{n - 1}} \qquad ( 11 )$$

$$\frac{1}{{\hat{Q}}_{ma {x}_{n}}} = \frac{1}{{\hat{Q}}_{m {ax}_{n - 1}}} + {kq}_{n} ( \frac{1}{{Q}_{m {ax}_{n}}} - \frac{1}{{\hat{Q}}_{ma {x}_{n - 1}}} ) \qquad ( 12 )$$

$${k q}_{n} = \frac{{δ}_{\frac{1}{{Q}_{m {ax}_{n}}}}^{2}}{{δ}_{\frac{1}{{Q}_{m {ax}_{n}}}}^{2} + {δ}_{\frac{1}{\hat{Q} m {ax}_{n - 1}}}^{2}} \qquad ( 13 )$$

$${δ}_{\frac{1}{{\hat{Q}}_{ma {x}_{n - 1}}}} = {( 1 - {kq}_{n} )}^{2} ( {δ}_{\frac{1}{{\hat{Q}}_{ma {x}_{n - 1}}}}^{2} ) + {kq}_{n}^{2} {δ}_{\frac{1}{{Q}_{m {ax}_{n}}}}^{2} \qquad ( 14 )$$

In the above equation 10, I is a measured current flowing through the battery cell, I_{offset} is a current offset error of the battery cell, and Δt is a duration of time over which ΔQₙ is determined (e.g., a duration of time over which the current flowing through the battery cell is summed). In the above equation 12,

$$\frac{1}{{\hat{Q}}_{m {ax}_{n}}}$$

is representative of an estimated value of Qₘₐₓ_{ₙ}, \hat{Q}ₘₐₓ_{_{n−1}} is an immediately preceding value of \hat{Q}ₘₐₓ_{ₙ}, and kqₙ is as shown in equation 13. In some examples,

$$\frac{1}{{\hat{Q}}_{ma {x}_{n}}}$$

has a fixed value, such as determined according to equation 12. In other examples,

$$\frac{1}{{\hat{Q}}_{ma {x}_{n}}}$$

is in normal distribution such that

$$\frac{1}{{\hat{Q}}_{ma {x}_{n}}}$$

may have a value within a range defined around the value of according to equation 12 plus or minus a variance associated with the normal distribution. In the above equation 13,

$${δ}_{\frac{1}{{Q}_{ma {x}_{n}}}}^{2}$$

is a variance associated with a normal distribution of

$$\frac{1}{{Q}_{ma {x}_{n}}} and {δ}_{\frac{1}{{\hat{Q}}_{ma {x}_{n - 1}}}}^{2}$$

is a variance associated with a normal distribution of

$$\frac{1}{{\hat{Q}}_{ma {x}_{n - 1}}}$$

and is as shown in equation 14.

For n=0, various assumptions may be made due to the unavailability fo certain measurements, metrics, or other information necessary for solving any one or more of the above equations 4 through 14. For example, \hat{Q}ₘₐₓ_{ₒ} may have a value indicated as a nominal capacity of the battery cell by the manufacturer of the battery cell (such as in a data sheet for the battery cell), and

$${δ}_{\frac{1}{{\hat{Q}}_{m {ax}_{0}}}}^{2} = {( \frac{{\hat{Q}}_{m {ax}_{0}}}{β} )}^{2}$$

where β represents an error in the capacity of the battery cell from the nominal capacity of the battery cell as indicated by the manufacturer and in some examples may be approximated as 0.2, and [symbol] ₀=SOC1₀.

Based on the above equations 4 through 14, and as shown in FIG. 6, the estimated SOC for a battery cell may be determined for the battery cell beginning with determining the OCV for the battery cell. At a first time (e.g., n=1), the term [symbol] Cₙ₋₁ is undefined. Therefore, for n=1, [symbol] C₁=SOC1₁. Again because [symbol] Cₙ₋₁ is undefined, \hat{Q}ₘₐₓ may be determined to approximately equal 1 with a variance of 0.01. For n=2 and greater values, [symbol] Cₙ may be determined directly based on the above equations 4 through 14. In this disclosure it is assumed that all values are in normal distribution with a variance defined according to error sources for the respective values.

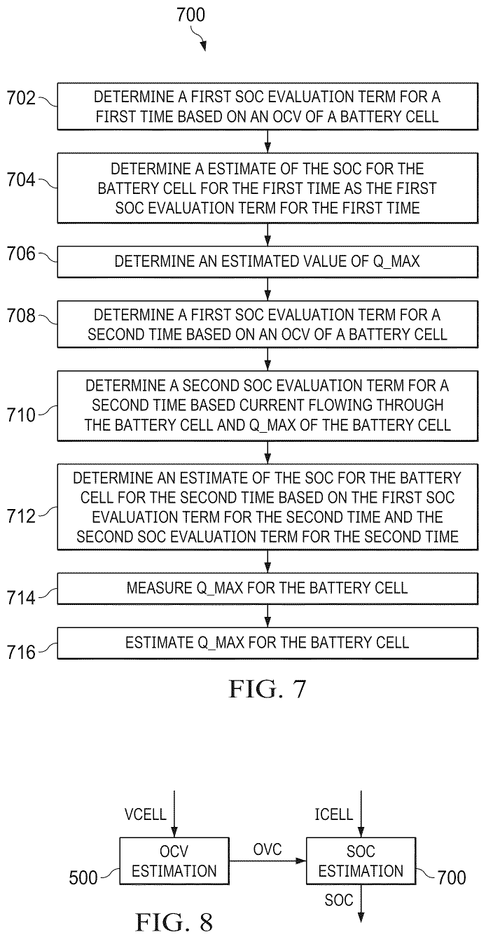

FIG. 7 is a flowchart of an example method 700 of SOC estimation. In an example, the method 700 is implemented at least in part by a controller, processor, microprocessor, or other device having computational and/or instruction execution capacity. In some examples, the method 700 is implemented at least in part by a secondary network node 106 for determining SOC of one or more battery cells 108 to which the secondary network node 106 is coupled. Additional example details of determining SOC for battery cells can be found in commonly assigned U.S. Patent Application Publication No. 2024/0337696, entitled “Residual State of Charge Runtime Update,” filed Jul. 31, 2023, which is incorporated by reference in its entirety.

At operation 702, a first SOC evaluation term for a first time is determined based on an OCV of a battery cell. In some examples, the OCV is determined based on measured values. In other examples, the OCV is estimated, such as based on one or more estimated values derived from one or more measured values. The first SOC evaluation term for the first time may be determined according to equation 5, as described above. In some examples, the first SOC evaluation term defines a voltage-based state of charge of the battery cell based on the open circuit voltage.

At operation 704, an estimate of the SOC for the battery cell for the first time is determined as the first SOC evaluation term for the first time. The SOC can be determined using equations (4)-(6) herein.

At operation 706, an estimated value of Qₘₐₓ for the first time is determined to be approximately equal 1. Qₘₐₓ can be estimated using equations (10) and (11) herein.

At operation 708, a first SOC evaluation term for a second time (which may be generalized to an n^{th} time throughout the description of the method 1400) is determined based on an OCV of a battery cell at the second time. The first SOC evaluation term for a second time may be determined in the same manner as the first SOC evaluation term for the first time at operation 1402, such as according to equation 5, as described above.

At operation 710, a second SOC evaluation term for the second time is determined based on current flowing through the battery cell and a Qₘₐₓ of the battery cell. The second SOC evaluation term for the first time may be determined according to equation 6, as described above. In some examples, the current flowing through the battery cell and the Qₘₐₓ of the battery cell may be determined according to equations 10 and 11, respectively, as described above. In some examples, the second SOC evaluation term defines a current-based state of charge of the battery cell based on a maximum charge capacity of the battery cell.

At operation 712, an estimate of the SOC for the battery cell for the second time is determined based on the first SOC evaluation term for the second time and the second SOC evaluation term for the second time. The estimate of the SOC for the battery cell for the second time may be determined according to equations 4 and 7, as described above.

At operation 714, Qₘₐₓ for the battery cell is measured. In some examples, Qₘₐₓ is determined by measuring a change in charge (ΔQ) of the battery cell over a period of time. Based on the change in charge, Qₘₐₓ may be determined, such as according to equation 11, as described above.

At operation 716, Qₘₐₓ for the battery cell is estimated. The estimated Qₘₐₓ, which may be indicated by Qₘₐₓ, may be determined according to the equation 12, as described above.

In some examples, the method 700 ends after operation 716. In other examples, the method 700 repeats operations 708 through 716 in loop, determining the estimate of the SOC for the battery cell at different points in time, such as based at least in part on values of OCV at different points in time, measured changes in charge of the battery cell over time, and the like.

FIG. 8 is a flowchart of an example method 800 of SOC estimation. In an example, the method 800 is implemented at least in part by a controller, processor, microprocessor, or other device having computational and/or instruction execution capacity. In some examples, the method 800 is implemented at least in part by a secondary network node 106 for determining an estimated OCV of one or more battery cells 108 and, using that estimated OCV, estimating SOC of the one or more battery cells 108 to which the secondary network node 106 is coupled. The OCV can be estimated using any of the approaches described herein, such as a voltage curve, a rest voltage, a least-square approach, a relaxation model, and/or a CARMA model. In an example, the method 800 is a combination of the methods 500 and 700. For example, the estimated OCV resulting from operation 516, or the recorded OCV resulting from operation 510, as appropriate, may be provided as an input to the method 700, such as at operation 702. Thus, in some examples, the method 700 of OCV estimation and the method 700 of SOC estimation may be implemented together as the method 800 by a same device, or multiple devices operating cooperatively, to estimate a future value of Vcell of a battery cell, determine an estimated OCV of the battery cell based on that estimated future value of Vcell, and determine a corresponding estimated SOC of that battery cell based at least in part on the estimated OCV of the battery cell.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail or more simply a “rail,” may also be referred to as a voltage terminal and may generally mean a common node or set of coupled nodes in a circuit at the same potential.

What is claimed is:

1. A device, configured to:
determine, at a first time, a first cell voltage of a battery cell;
determine, at a second time, a second cell voltage of the battery cell;
estimate a future cell voltage of the battery cell using the first cell voltage and the second cell voltage, the future cell voltage for a third time subsequent to the second time; and
estimate an open circuit voltage of the battery cell using the estimated future cell voltage of the battery cell, an impedance of the battery cell, and a current measurement of the battery cell at the second time.

2. The device of claim 1, wherein the device is configured to estimate the future cell voltage of the battery cell according to Vcellₓ=(x−n)*(Vcellₙ−Vcellₙ₋₁)+Vcellₙ, where Vcellₓ is the future cell voltage of the battery cell at a sample index of x, Vcellₙ is the second cell voltage of the battery cell taken at a sample index of n, and Vcellₙ₋₁ is the first cell voltage of the battery cell taken at a sample index of n−1.

3. The device of claim 1, wherein the second time corresponds to an n^{th} sample of the cell voltage of the battery cell and the first time corresponds to an n−1^{th} sample of the cell voltage of the battery cell.

4. The device of claim 1, wherein the device is configured to estimate the open circuit voltage of the battery cell according to OCV=Vcellₓ+Iₙ*Rcell, where Vcellₓ is the future cell voltage of the battery cell at a sample index of x, Iₙ current measurement of the battery cell at the second time taken at a sample index of n, and Rcell is an impedance of the battery cell.

5. The device of claim 1, wherein the third time is greater than or equal to 2048 seconds, the second time is greater than 128 seconds, and the first time is one-half the second time.

6. The device of claim 1, further configured to:
determine a voltage-based state of charge of the battery cell based on the open circuit voltage;
determine a current-based state of charge of the battery cell based on a maximum charge capacity of the battery cell; and
estimate a state of charge of the battery cell based on the voltage-based state of charge and the current-based state of charge.

7. The device of claim 6, wherein the estimated state of charge of the battery cell is determined according to: SOC1ₙ+ksₙ(SOC2ₙ−SOC1ₙ), where SOC1ₙ is the voltage-based state of charge of the battery cell, SOC2ₙ is the current-based state of charge of the battery cell, and ksₙ is a variance factor relating a variance of the voltage-based state of charge of the battery cell to a sum of variance of the voltage-based state of charge of the battery cell and the current-based state of charge of the battery cell.

8. A method, comprising:
determining, at a first time via a controller, a first cell voltage of a battery cell;
determining, at a second time via the controller, a second cell voltage of the battery cell; and
estimating, via the controller, a future cell voltage of the battery cell using the first cell voltage and the second cell voltage, the future cell voltage for a third time subsequent to the second time.

9. The method of claim 8, comprising estimating the future cell voltage of the battery cell according to Vcellₓ=(x−n)*(Vcellₙ−Vcellₙ₋₁)+Vcellₙ, where Vcellₙ, is the future cell voltage of the battery cell at a sample index of x, Vcellₙ is the second cell voltage of the battery cell taken at a sample index of n, and Vcellₙ₋₁ is the first cell voltage of the battery cell taken at a sample index of n−1.

10. The method of claim 8, wherein the second time corresponds to an n^{th} sample of the cell voltage of the battery cell and the first time corresponds to an n−1^{th} sample of the cell voltage of the battery cell.

11. The method of claim 8, further comprising estimating, via the controller, an open circuit voltage of the battery cell using the cell voltage of the battery cell and a rest voltage of the battery cell.

12. The method of claim 11, comprising estimating the open circuit voltage of the battery cell according to OCV=Vcellₓ+Iₙ*Rcell, where Vcellₓ is the future cell voltage of the battery cell at a sample index of x, Iₙ current measurement of the battery cell at the second time taken at a sample index of n, and Rcell is an impedance of the battery cell.

13. The method of claim 11, further comprising:
determining a voltage-based state of charge of the battery cell based on the open circuit voltage;
determining a current-based state of charge of the battery cell based on a maximum charge capacity of the battery cell; and
estimating a state of charge of the battery cell based on the voltage-based state of charge and the current-based state of charge.

14. The method of claim 13, wherein the estimated state of charge of the battery cell is determined according to: SOC1ₙ+ksₙ(SOC2ₙ−SOC1ₙ), where SOC1ₙ is the voltage-based state of charge of the battery cell, SOC₂, is the current-based state of charge of the battery cell, and ksₙ is a variance factor relating a variance of the voltage-based state of charge of the battery cell to a sum of variance of the voltage-based state of charge of the battery cell and the current-based state of charge of the battery cell.

15. The method of claim 13, wherein the current-based state of charge of the battery cell is determined according to a prior estimated state of charge of the battery cell, a change in charge of the battery cell, and an estimated maximum charge capacity of the battery cell.

16. A system, comprising:
a battery;
a processor; and
a management circuit coupled to the battery and the processor, the management circuit configured to:
determine, at a first time, a first cell voltage of a battery cell;
determine, at a second time, a second cell voltage of the battery cell;
estimate a future cell voltage of the battery cell using the first cell voltage and the second cell voltage, the future cell voltage for a third time subsequent to the second time;
estimate an open circuit voltage of the battery cell using the estimated future cell voltage of the battery cell, an impedance of the battery cell, and a current measurement of the battery cell at the second time; and
provide the estimated open circuit voltage of the battery to the processor.

17. The system of claim 16, wherein the management circuit is configured to estimate the future cell voltage of the battery cell according to Vcellₓ=(x−n)*(Vcellₙ−Vcellₙ₋₁)+Vcellₙ, where Vcellₓ is the future cell voltage of the battery cell at a sample index of x, Vcellₙ is the second cell voltage of the battery cell taken at a sample index of n, and Vcellₙ₋₁ is the first cell voltage of the battery cell taken at a sample index of n−1.

18. The system of claim 17, wherein the second time corresponds to an n^{th} sample of the cell voltage of the battery cell and the first time corresponds to an n−1^{th} sample of the cell voltage of the battery cell.

19. The system of claim 18, wherein the management circuit is configured to estimate the open circuit voltage of the battery cell according to OCV=Vcellₓ+Iₙ*Rcell, where Vcellₓ is the future cell voltage of the battery cell at a sample index of x, Iₙ current measurement of the battery cell at the second time taken at a sample index of n, and Rcell is the impedance of the battery cell.

20. The system of claim 16, wherein the management circuit is configured to:
determine a voltage-based state of charge of the battery cell based on the open circuit voltage;
determine a current-based state of charge of the battery cell based on a maximum capacity of the battery; and
estimate a state of charge of the battery cell based on the voltage-based state of charge and the current-based state of charge.
